(19) United States
(12) Patent Application Publication
(10) Pub. No.: US 2024/0162091 A1
(43) Pub. Date: May 16, 2024

(54) ELEMENT CHIP MANUFACTURING METHOD

(71) Applicant: Panasonic Intellectual Property Management Co., Ltd., Osaka (JP)

(72) Inventors: Hidehiko KARASAKI, HYOGO (JP); Shogo OKITA, HYOGO (JP); Toshiyuki TAKASAKI, OSAKA (JP); Ryota FURUKAWA, OSAKA (JP)

(21) Appl. No.: 18/501,124

(22) Filed: Nov. 3, 2023

(30) Foreign Application Priority Data
Nov. 15, 2022 (JP) 2022-182612

(51) Int. Cl. H01L 21/78; H01L 21/308

(52) U.S. Cl. CPC H01L 21/78; H01L 21/3086; H01L 21/3065

(57) ABSTRACT

The disclosed element chip manufacturing method includes: a first step of imparting hydrophilicity to a first surface 11 of a substrate 1, the first surface 11 including element regions 11A and dicing regions 11B defining the element regions 11A; a second step of applying a raw material liquid containing a water-soluble resin onto the first surface 11, to form a water-soluble resin layer 20 on the first surface 11; a third step of applying a laser beam to the water-soluble resin layer 20 covering the dicing regions 11B, to form openings 20a that expose the dicing regions 11B, in the water-soluble resin layer 20; a fourth step of etching the dicing regions 11B exposed at the openings 20a, with plasma, to obtain element chips 30; and a fifth step of removing the water-soluble resin layer 20 by bringing the element chips 30 into contact with a water-containing cleaning liquid.

### CROSS REFERENCE TO RELATED APPLICATION

The present application is based on and claims priority under 35 U.S.C. § 119 with respect to the Japanese Patent Application No. 2022-182612 filed on Nov. 15, 2022, of which entire content is incorporated herein by reference into the present application.

### TECHNICAL FIELD

The present disclosure relates to an element chip manufacturing method.

### BACKGROUND

Conventionally, there has been known a technique of obtaining a plurality of element chips by singulating a substrate including a plurality of element regions and dicing regions defining the element regions, with plasma (e.g., Patent Literature 1: Japanese Laid-Open Patent Publication No. 2019-212764). The element chip manufacturing method of Patent Literature 1 includes a step of applying a mixture containing a water-soluble resin onto a surface of the substrate, to form a protective film containing the water-soluble resin on the surface, a step of applying a laser beam to part of the protective film, to expose the surface of the substrate in the dicing regions, a step of plasma etching the substrate in the dicing regions, to singulate the substrate into a plurality of element chips, and a step of removing the protective film at portions covering the element regions.

However, when, for example, a circuit layer or the like is present on the surface of the substrate, the laser beam to be applied to the protective film is set at a relatively high output power. When the output power of the laser beam is high, a portion where the adhesion strength is weakened may occur at the interface between the surface of the substrate and the protective film. In this case, the precision of plasma etching is lowered, the side surfaces of the obtained element chips are roughened. In such element chips, stress concentrates at part of the side surfaces during handling, and chipping easily occurs (i.e., the die strength is low). Under such circumstances, one object of the present disclosure is to increase the die strength of the element chips.

### SUMMARY

One aspect of the present disclosure relates to an element chip manufacturing method. The manufacturing method includes: a first step of imparting hydrophilicity to a first surface of a substrate, the first surface including a plurality of element regions and dicing regions defining the element regions; a second step of applying a raw material liquid containing a water-soluble resin onto the first surface, to form a water-soluble resin layer on the first surface; a third step of applying a laser beam to the water-soluble resin layer covering the dicing regions, to form openings that expose the dicing regions, in the water-soluble resin layer; a fourth step of etching the dicing regions exposed at the openings, with plasma, to obtain a plurality of element chips; and a fifth step of removing the water-soluble resin layer by bringing the plurality of element chips into contact with a water-containing cleaning liquid.

According to the present disclosure, it is possible to improve the die strength of the element chips.

### BRIEF DESCRIPTION OF THE DRAWINGS

FIG. 1 is a flow chart of one example of an element chip manufacturing method according to the present disclosure.

FIGS. 2A and 2B schematically illustrate a conveying carrier and a substrate held thereon, where FIG. 2A is a top view, and FIG. 2B is a cross-sectional view taken along the line B-B.

FIG. 3 is a diagram of a first step of Embodiment 1, shown by enlarging part of a substrate.

FIG. 4 is a diagram of a second step, shown by enlarging part of the substrate.

FIG. 5 is a diagram of a third step, shown by enlarging part of the substrate.

FIG. 6 is a diagram of a fourth step, shown by enlarging part of the substrate.

FIG. 7 is a diagram of a fifth step, shown by enlarging part of the substrate.

FIG. 8 is a diagram of a first step of Embodiment 2, shown by enlarging part of a substrate.

### DETAILED DESCRIPTION

Embodiments of an element chip manufacturing method according to the present disclosure will be described below by way of examples. It is to be noted, however, that the present disclosure is not limited to the examples described below. In the description below, specific numerical values and materials are exemplified in some cases, but other numerical values and materials may be applied as long as the effects of the present disclosure can be achieved.

An element chip manufacturing method according to the present disclosure is to obtain a plurality of element chips by plasma etching a substrate. The element chip manufacturing method according to the present disclosure includes a first step, a second step, a third step, a fourth step, and a fifth step.

In the first step, hydrophilicity is imparted to a first surface of a substrate. The first surface of the substrate includes a plurality of element regions and dicing regions (sometimes called streets) defining the element regions. The substrate may have a second surface opposite the first surface. The substrate may be a semiconductor substrate (e.g., can be formed of silicon, gallium arsenide, gallium nitride, or silicon carbide). The element regions may have, for example, a semiconductor layer and a wiring layer. Here, “imparting hydrophilicity to the first surface of the substrate” can be rephrased as “enhancing the hydrophilicity of the first surface of the substrate.” For example, it suffices that the contact angle between the first surface and water becomes smaller after than before the first step, and desirably, the above contact angle becomes smaller by, for example, 30% or more than before the first step. On the first surface of the substrate, a semiconductor (e.g., silicon) as mentioned above may be exposed, a resin film such as a polyimide resin film may be disposed, and a metal material such as a metal wiring layer may be disposed.

In the second step, a raw material liquid containing a water-soluble resin is applied onto the first surface of the substrate, to form a water-soluble resin layer on the first surface. Over the first surface imparted with high hydrophilicity by the first step, the raw material liquid containing the water-soluble resin wets and spreads substantially uniformly, and the water-soluble resin layer is formed with high adhesiveness. Examples of the water-soluble resin include polyvinyl alcohol, water-soluble polyester, polystyrenesulfonic acid, polyacrylic acid, polymethacrylic acid, polyacrylamide, 2-acrylamido-2-methylpropanesulfonic acid, oxazole-based water-soluble polymer (e.g., oxazole-2-ethyl-4,5-dihydro homopolymer), or salts thereof (e.g., alkali metal salts, ammonium salts). For the application of the raw material liquid containing a water-soluble resin, a spray coating technique of atomizing the raw material liquid and spraying it onto the substrate may be adopted, or a spin coating technique of dropping the raw material liquid onto the substrate and spinning the substrate may be adopted.

In the third step, a laser beam is applied to the water-soluble resin layer covering the dicing regions, to form openings that expose the dicing regions, in the water-soluble resin layer. In the third step, in addition to the water-soluble resin layer covering the dicing regions, the metal material present in the dicing regions may be removed by laser beam application. In this case, it is necessary to use a laser beam with high output power. However, the water-soluble resin layer with high adhesiveness is formed on the first surface through the first and second steps. Therefore, even in the vicinity of the dicing regions, the adhesion strength between the first surface and the water-soluble resin layer can be maintained sufficiently high.

In the fourth step, the dicing regions exposed at the openings are etched with plasma, to obtain a plurality of element chips. Due to the high adhesion strength between the first surface and the water-soluble resin layer in the vicinity of the dicing regions, the above plasma etching can be done with high precision, and the side surfaces of the obtained element chips can be sufficiently smooth. The above plasma etching may be performed using the so-called Bosch process.

In the fifth step, the water-soluble resin layer is removed by bringing the plurality of element chips into contact with a water-containing cleaning liquid. The removal of the water-soluble resin layer does not require the use of an organic solvent. Therefore, the burden to the environment can be lessened as compared when a protective film made of an organic material is used.

The first step may include a plasma processing step of applying an oxygen-containing plasma to the first surface of the substrate. The inventors of the present application have experimentally found that the hydrophilicity of the first surface is enhanced by application of an oxygen-containing plasma. As the mechanism thereof, it can be considered that the surface of the substrate is oxidized, leading to increased polarity, that the first surface is roughened by the oxygen-containing plasma, leading to enhanced wettability, and so on. For the application of the oxygen-containing plasma, a plasma processing apparatus (e.g., plasma cleaner) may be used. The content of oxygen relative to the total amount of gas contained in the atmosphere for generating an oxygen-containing plasma may be 50 vol % or more and 100 vol % or less, or may be 80 vol % or more and 100 vol % or less. The oxygen-containing plasma can be generated by, for example, supplying oxygen at 100 sccm into a processing chamber of a parallel plate-type plasma processing apparatus, and with the pressure in the processing chamber adjusted to 40 to 60 Pa, applying a high-frequency power of about 100 to 200 W to the electrodes for plasma generation provided in the plasma processing apparatus. The application time of the oxygen-containing plasma is, for example, about 20 to 40 seconds.

The first step may include a rinse step of bringing the first surface of the substrate into contact with a rinse liquid containing at least one of a first surfactant, isopropyl alcohol, acetone, and ethanol. Due to the attachment of the above rinse liquid, the hydrophilicity of the first surface is likely to be enhanced. The first surfactant may be a neutral nonionic surfactant. Examples of the first surfactant include polyoxyalkylene alkyl ethers, polyoxyalkylene alkyl aryl ethers, polyoxyalkylene fatty acid esters, sorbitan fatty acid esters, and polyoxyethylene-polyoxypropylene copolymers. Here, the alkylene group is preferably an ethylene group, a propylene group, and the like.

The raw material liquid containing a water-soluble resin may further contain a second surfactant. The second surfactant may be a neutral nonionic surfactant. Examples of the second surfactant include surfactants exemplified as the first surfactant. The composition of the second surfactant may be the same as or different from that of the first surfactant.

The second step may be started within a predetermined time after the first step is completed. If a long time has passed after the completion of the first step, the hydrophilicity of the first surface may decrease. Therefore, by applying the raw material liquid containing the water-soluble resin onto the first surface within a predetermined time during which the hydrophilicity of the first surface does not decrease so much, the adhesion strength between the first surface and the water-soluble resin layer can be sufficiently increased. The predetermined time may be, for example, one hour or less.

If the second process is not started within a predetermined time after the first process is completed, the first process may be performed again. In this way, even when the hydrophilicity of the first surface has decreased, the hydrophilicity of the first surface can be enhanced by performing the first step again. The predetermined time may be, for example, one hour or less. It is desirable to start the second step within a predetermined time after the first step is performed again.

As described above, according to the present disclosure, by forming a water-soluble resin layer on the first surface having high hydrophilicity, plasma etching can be performed with high precision, and this can improve the die strength of the element chips. Furthermore, according to the present disclosure, it is possible to lessen the burden to the environment by using the raw material liquid containing a water-soluble resin.

In the following, an example of the element chip manufacturing method according to the present disclosure will be specifically described with reference to the drawings. The steps as described above can be applied to the steps of the below-described example of the element chip manufacturing method. The steps of the below-described examples of the element chip manufacturing method can be modified based on the description above. The matters as described below may be applied to the above embodiments. Of the steps of the below-described examples of the element chip manufacturing method, the steps which are not essential to the element chip manufacturing method according to the present disclosure may be omitted. The figures below are schematic and not intended to accurately reflect the shape and the number of the actual members.

### Embodiment 1

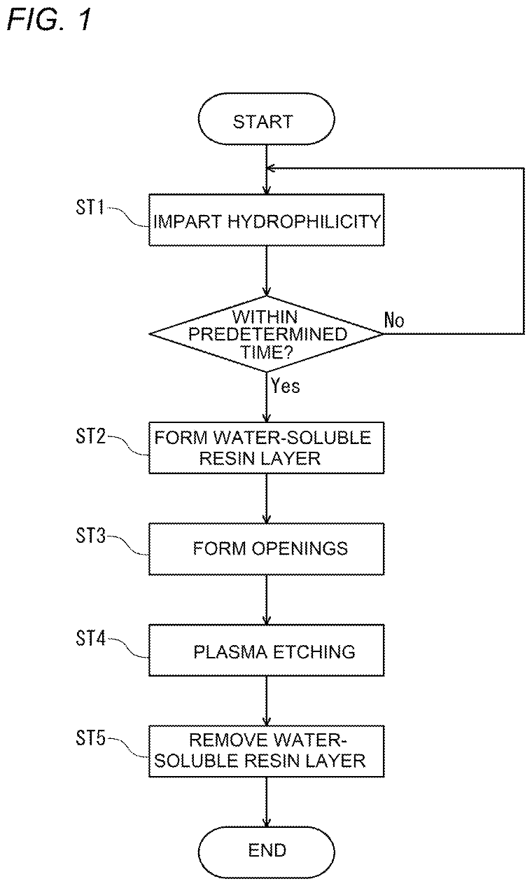

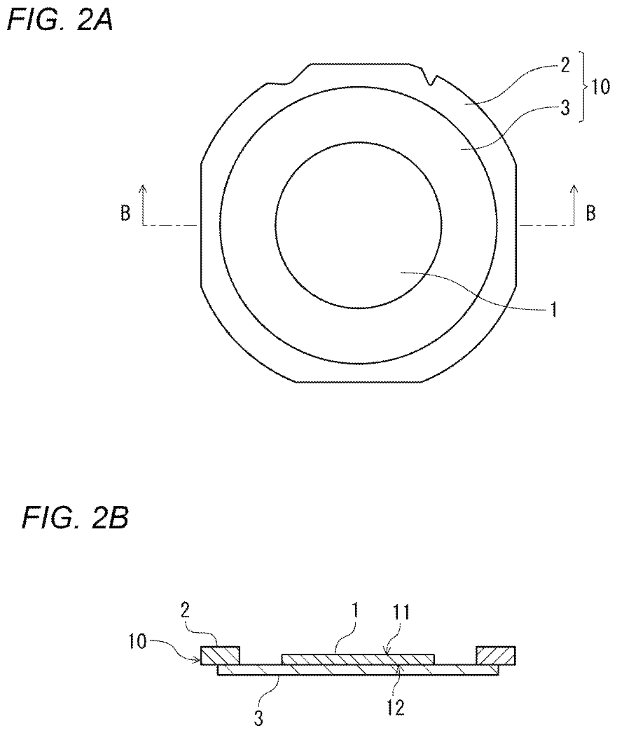

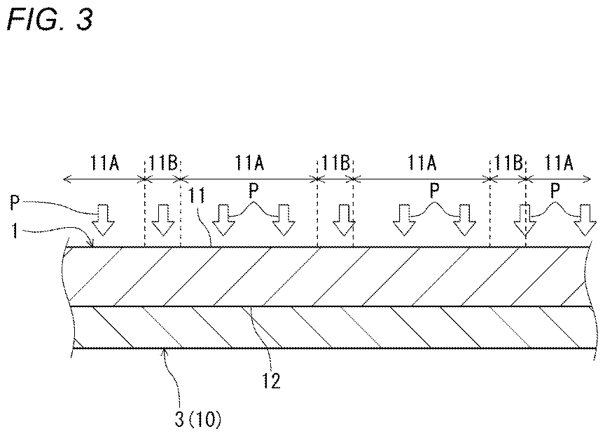

Embodiment 1 of the present disclosure will be described. An element chip manufacturing method of the present embodiment includes, as shown in FIG. 1, a first step ST1, a second step ST2, a third step ST3, a fourth step ST4, and a fifth step ST5. Prior to the first step ST1, a substrate 1 as illustrated in FIGS. 2A and 2B is prepared. The substrate 1 has a first surface 11 and a second surface 12. The first surface 11 includes, as shown in FIG. 3 and other figures, a plurality of element regions 11A and dicing regions 11B defining the element regions 11A. The substrate 1 is held on a conveying carrier 10 having a holding sheet 3 and a frame 2. The substrate 1 may be subjected to the first step ST1 to the fifth step ST5 while being held on the conveying carrier 10 with the second surface 12 attached to the holding sheet 3.

In the first step ST1, as shown in FIG. 3, hydrophilicity is imparted to the first surface 11 of the substrate 1. The first step ST1 includes a plasma processing step of applying an oxygen-containing plasma to the first surface 11 of the substrate 1. In the present embodiment, the application of the oxygen-containing plasma is performed using a plasma cleaner, but is not limited thereto.

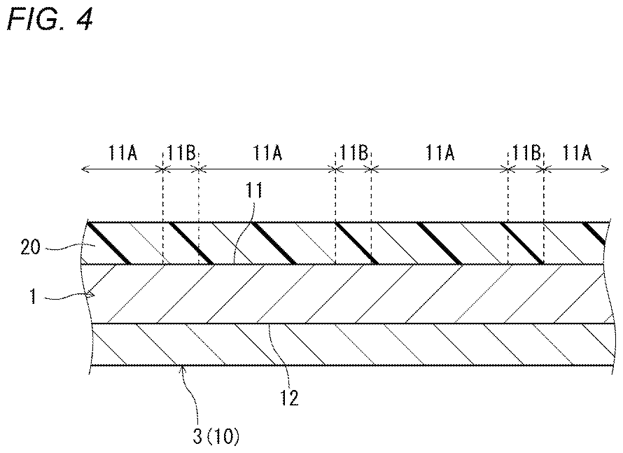

In the second step ST2, as shown in FIG. 4, a raw material liquid containing a water-soluble resin is applied onto the first surface 11 of the substrate 1, to form a water-soluble resin layer 20 on the first surface 11. The application of the raw material liquid may be performed, for example, using a spin coating technique or a spray coating technique. As shown in FIG. 1, the second step ST2 is started within a predetermined time after the first step ST1 is completed. On the other hand, if the second step ST2 is not started within the predetermined time after the completion of the first step ST1, the first step ST1 is performed again.

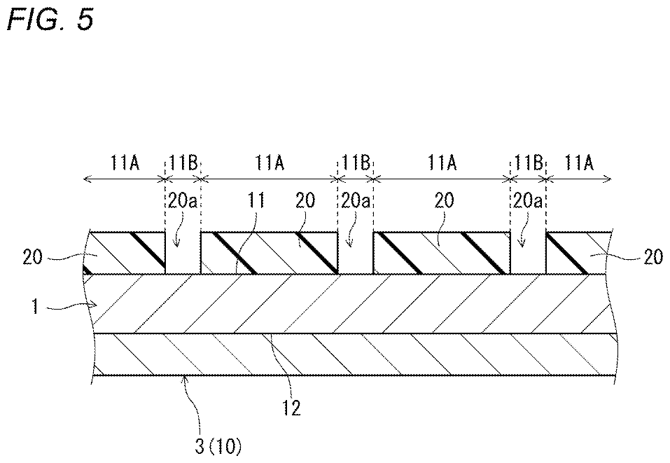

In the third step ST3, as shown in FIG. 5, a laser beam is applied to the water-soluble resin layer 20 covering the dicing regions 11B, to form openings 20a that expose the dicing regions 11B, in the water-soluble resin layer 20. In the third step ST3, if a metal material is present on the dicing regions 11B, the metal material may be removed together with the water-soluble resin layer 20 by the laser beam.

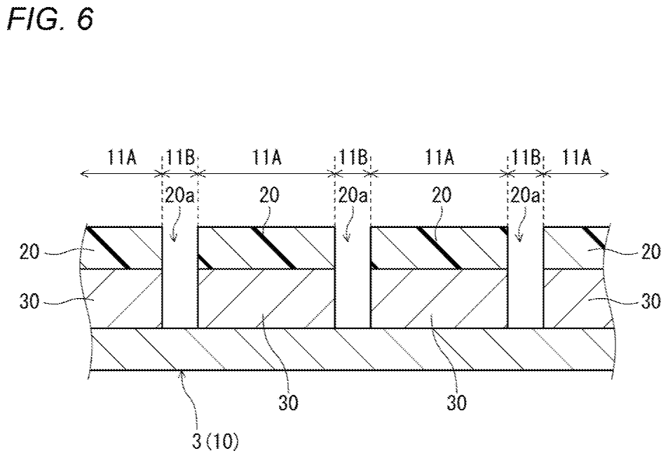

In the fourth step ST4, as shown in FIG. 6, a plurality of element chips 30 are obtained by etching the dicing regions 11B exposed at the openings 20a, with plasma. In the present embodiment, the plasma etching is performed using a plasma dicer, but is not limited thereto. The plasma etching may be performed using a Bosch process or a non-Bosch process.

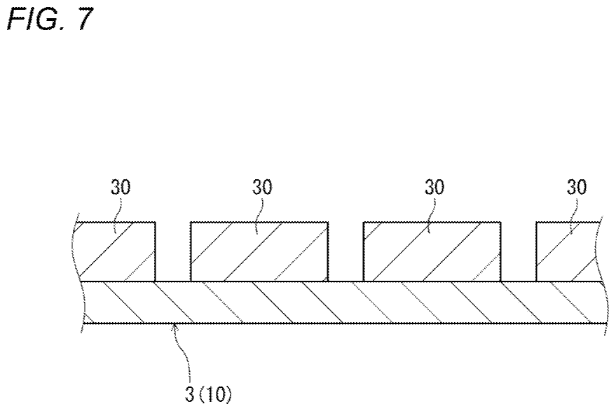

In the fifth step ST5, as shown in FIG. 7, the water-soluble resin layer 20 is removed by bringing the plurality of element chips 30 into contact with a water-containing cleaning liquid. In the present embodiment, the water-containing cleaning liquid is water, but is not limited thereto.

### Embodiment 2

Embodiment 2 of the present disclosure will be described. The element chip manufacturing method of the present embodiment differs from that of the above Embodiment 1 in the means for imparting hydrophilicity. In the following, the difference from the above Embodiment 1 will be mainly described.

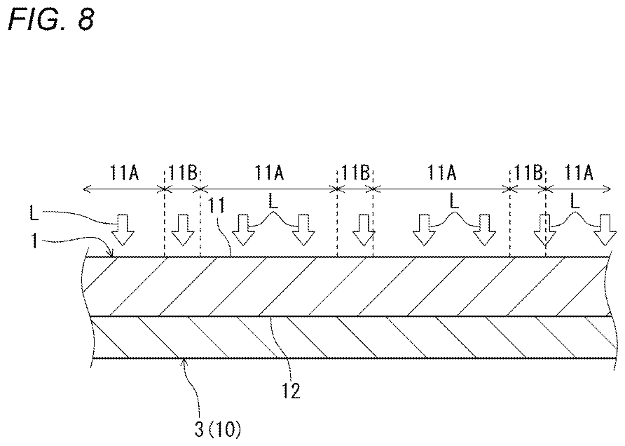

As shown in FIG. 8, the first step ST1 includes a rinse step of bringing the first surface 11 of the substrate 1 into contact with a rinse liquid L containing at least one of a first surfactant, isopropyl alcohol, acetone, and ethanol. The rinse liquid L may be sprayed onto the first surface 11 of the substrate 1 using a sprayer (not shown). The raw material liquid used in the second step ST2 of the present embodiment contains a second surfactant.

### SUPPLEMENTARY NOTE

The following techniques are disclosed by the foregoing description of embodiments.

(Technique 1)

An element chip manufacturing method, comprising:
a first step of imparting hydrophilicity to a first surface of a substrate, the first surface including a plurality of element regions and dicing regions defining the element regions;
a second step of applying a raw material liquid containing a water-soluble resin onto the first surface, to form a water-soluble resin layer on the first surface;
a third step of applying a laser beam to the water-soluble resin layer covering the dicing regions, to form openings that expose the dicing regions, in the water-soluble resin layer;
a fourth step of etching the dicing regions exposed at the openings, with plasma, to obtain a plurality of element chips; and
a fifth step of removing the water-soluble resin layer by bringing the plurality of element chips into contact with a water-containing cleaning liquid.

(Technique 2)

The element chip manufacturing method according to technique 1, wherein the first step includes a plasma processing step of applying an oxygen-containing plasma to the first surface.

(Technique 3)

The element chip manufacturing method according to technique 1, wherein the first step includes a rinse step of bringing the first surface into contact with a rinse liquid containing at least one of a first surfactant, isopropyl alcohol, acetone, and ethanol.

(Technique 4)

The element chip manufacturing method according to any one of techniques 1 to 3, wherein the raw material liquid further contains a second surfactant.

(Technique 5)

The element chip manufacturing method according to any one of techniques 1 to 4, wherein the second step is started within a predetermined time after the first step is completed.

(Technique 6)

The element chip manufacturing method according to any one of techniques 1 to 4, wherein if the second step is not started within a predetermined time after the first step is completed, the first step is performed again.

The present disclosure is applicable to an element chip manufacturing method.

### REFERENCE NUMERALS

1: substrate
   11: first surface
      11A: element region
      11B: dicing region
   12: second surface
10: conveying carrier
   2: frame
   3: holding sheet
20: water-soluble resin layer
   20a: opening
30: element chip
L: rinse liquid
P: oxygen-containing plasma

What is claimed is:

1. An element chip manufacturing method, comprising:
a first step of imparting hydrophilicity to a first surface of a substrate, the first surface including a plurality of element regions and dicing regions defining the element regions;
a second step of applying a raw material liquid containing a water-soluble resin onto the first surface, to form a water-soluble resin layer on the first surface;
a third step of applying a laser beam to the water-soluble resin layer covering the dicing regions, to form openings that expose the dicing regions, in the water-soluble resin layer;
a fourth step of etching the dicing regions exposed at the openings, with plasma, to obtain a plurality of element chips; and
a fifth step of removing the water-soluble resin layer by bringing the plurality of element chips into contact with a water-containing cleaning liquid.

2. The element chip manufacturing method according to claim 1, wherein the first step includes a plasma processing step of applying an oxygen-containing plasma to the first surface.

3. The element chip manufacturing method according to claim 1, wherein the first step includes a rinse step of bringing the first surface into contact with a rinse liquid containing at least one of a first surfactant, isopropyl alcohol, acetone, and ethanol.

4. The element chip manufacturing method according to claim 1, wherein the raw material liquid further contains a second surfactant.

5. The element chip manufacturing method according to claim 1, wherein the second step is started within a predetermined time after the first step is completed.

6. The element chip manufacturing method according to claim 1, wherein if the second step is not started within a predetermined time after the first step is completed, the first step is performed again.
